(19) United States
(12) Patent Application Publication
(10) Pub. No.: US 2023/0366956 A1
(43) Pub. Date: Nov. 16, 2023

(54) THREE-AXIS HALL MAGNETOMETER

(71) Applicants: SHANGHAI ORIENT-CHIP TECHNOLOGY CO., LTD, Shanghai (CN); ZHEJIANG HENGTUO ELECTRONIC TECHNOLOGY CO., LTD, Jiaxing (CN); SHENZHEN ORIENT-TOP MICROELECTRONICS CO., LTD, Longgan District, Shenzhen (CN)

(72) Inventors: Jie LUO, Shanghai (CN); Fude YUAN, Shanghai (CN); Jiankui WANG, Shanghai (CN); Xiaoming ZHENG, Shanghai (CN)

(21) Appl. No.: 18/029,274

(22) PCT Filed: Sep. 30, 2020
(86) PCT No.: PCT/CN2020/119153

§ 371 Date: Mar. 29, 2023

(51) Int. Cl. G01R 33/07; H10N 52/80

(52) U.S. Cl. CPC G01R 33/077; H10N 52/80

(57) ABSTRACT

A three-axis Hall magnetometer includes magnetic beam deflection structures located on a first plane and a plurality of vertical Hall assemblies located on a second plane without any planar Hall assembly. Each magnetic beam deflection structure is in an elongated shape and has a length-width ratio greater than 2. The magnetic beam deflection structure includes a first-type magnetic beam deflection structure, which extends in a first direction on the first plane. The sensing direction of each vertical Hall assembly is parallel to the first plane. The vertical Hall assemblies include first-type vertical Hall assemblies and second-type vertical Hall assemblies located near one long side of the first-type magnetic beam deflection structure. The plurality of vertical Hall assemblies further include third-type vertical Hall assemblies which have a sensing direction different from those of the first-type vertical Hall assemblies and the second-type vertical Hall assemblies.

### FIELD OF THE APPLICATION

The present application relates to a three-axis magnetometer, in particular to a three-axis Hall magnetometer.

### BACKGROUND OF THE APPLICATION

Magnetometers with three-axis linear output play an important role in the application of modern science and technology. A variety of functions can be realized, such as angle measurement, position or displacement measurement, and azimuth measurement. Its application fields range from industries, automobiles, various motor controls, to unmanned aerial vehicles, smart appliances or tools in the commercial field, as well as consumer electronic products such as smart phones and virtual reality entertainment products.

Among various technologies of magnetic sensing, the magnetometer realized by Hall Effect is one of the oldest and most mature technologies. The advantages and characteristics of Hall magnetometers are the linear output with high linearity of magnetic field strength, negligible magnetic hysteresis effect, and compatibility of the semiconductor manufacturing process. Among them, the compatibility of semiconductor manufacturing process makes it a competitor with great cost advantage. On the other hand, compared with other technology, especially the magnetoresistive technology, the lower sensitivity and the single sensing axis are the two main limitations of Hall technology in application.

At present, there are various existing technologies that can realize the three-axis linear output of the magnetometer.

As shown in FIG. 1, at present, various existing technologies are often based on a typical planar Hall assembly, which is disposed on a substrate for carrying and has two pairs of electrodes opposite to each other. Among them, the substrate can be a silicon chip, the planar Hall device is an N well on the substrate at this time, and in this case, the substrate and the planar Hall device are integrally formed. The substrate can also be a carrier plate on which the planar Hall assembly is placed, and in this case, the planar Hall assembly and the Hall device are two separate parts. The electrodes can be connected to the planar Hall assembly by passing through the substrate, or it can be connected to the planar Hall assembly by wire bonding without passing through the substrate. One pair of electrodes is connected to the power supply terminal Vdd and the ground terminal Gnd, while the other pair of electrodes is connected to the first output terminal V1 and the second output terminal V2. When the applied magnetic field is zero (B=0), the direction of the average current is shown by the solid arrow CL1 in FIG. 1, wherein the average current flows vertically from the power terminal Vdd to the ground terminal Gnd. When an applied magnetic field parallel to the D3 direction in the figure (B//D3) appears, the direction of the average current CL deflects towards the output terminal V1 due to the Lorentz force, as shown by the dotted arrow CL2 in FIG. 1. The deflection of the current creates an electric field between the first output terminal V1 and the second output terminal V2, which is the output of the planar Hall assembly. A typical planar Hall assembly only generates an output for the magnetic field component that is perpendicular to the plane of the substrate (i.e., perpendicular to the paper of FIG. 1).

In many applications, three-axis magnetic field sensing is necessary. Some methods to realize the three-axis magnetic field sensing by using Hall assemblies have been proposed and made into products for industrial, commercial and consumer fields.

### The First Prior Art

The three-axis Hall magnetometer provided by the first prior art uses a typical planar Hall assembly as shown in FIG. 1, wherein the planar Hall assembly is combined with two magnetic beam sensors. The planar Hall assembly senses the magnetic field component perpendicular to the plane of the substrate, and the two magnetic beam sensors located in the plane of the substrate sense the magnetic field components in two directions that are perpendicular to each other and parallel to the plane of the substrate. The magnetic beam sensor is composed of a ferromagnetic core and a conductor coil wound on the magnetic core, and its output can be the change of the inductive reactance caused by the magnetic field or the change of the magnetic beam caused by the magnetization of the magnetic core in the coil. The sensitivity of the magnetic beam sensor is about two orders of magnitude higher than that of the Hall device. The magnetic beam sensor is mainly used for geomagnetic measurement. The magnetic beam sensor is relatively sensitive when measuring a small magnetic field.

The disadvantage of the first prior art above is: since the magnetic saturation point of the magnetic core of the magnetic beam sensor is below 20 Gauss in magnetic field intensity and the magnetic beam sensor loses its function when the magnetic core is saturated, the three-axis Hall magnetometer formed by combining the planar Hall assembly and the magnetic beam sensors in this way will be limited by the magnetic beam sensors, and the narrow working range is a major limitation of this design.

### The Second Prior Art

The three-axis Hall magnetometer provided by the second prior art, that is, another way to realize the three-axis sensing, is to use a typical planar Hall assembly in combination with two anisotropic magnetoresistive assemblies on the same chip. The planar Hall assembly senses the magnetic field component perpendicular to the direction of the substrate, while the two anisotropic magnetoresistive assemblies sense the magnetic field components in two directions that are perpendicular to each other and parallel to the plane of the substrate.

The disadvantage of the second prior art is: although the sensitivity of the anisotropic magnetoresistive assembly is about two orders of magnitude higher than that of the Hall assembly, its working range is generally less than 30 Gauss. The narrow working range is also a major limitation of this design.

### The Third Prior Art

As shown in FIG. 2, the three-axis Hall magnetometer provided by the third prior art is a three-axis Hall magnetometer formed by only using typical planar Hall assemblies 301. The three-axis Hall magnetometer consists of four typical planar Hall assemblies 301 that sense the magnetic field components perpendicular to the plane of the substrate, and a magnetic beam deflection structure 302. Therefore, the four typical planar Hall assemblies 301 only sense the magnetic field component perpendicular to the plane of the substrate, and the magnetic field component parallel to the plane of the substrate is measured by deflecting the component parallel to the substrate to a vertical direction through the magnetic beam deflection structure 302. The magnetic beam deflection structure 302 is disk-shaped. The planar Hall assemblies 301 are disposed oppositely to each other in pairs, and the two pairs are perpendicular to each other. The distances between four planar Hall assemblies 301 are equal, and their positions are close to the edge of the magnetic beam deflection structure 302.

As shown in FIG. 3, the planar Hall device is embedded in the substrate, and is a part of the substrate. The substrate is a silicon chip, which is used to carry the Hall device. Generally, the planar Hall assembly 301 is an N-well inside the substrate, and the magnetic beam deflection structure 302 is a soft magnetic ferromagnetic material with high permeability, which is placed on the substrate. From the side view shown in FIG. 3, the planar Hall device and the magnetic beam deflection structure 302 are in the relation between the upper and lower, and the planar Hall device and the magnetic beam deflection structure 302 are separate from each other without direct contact. The planar Hall device is located near the edge below the magnetic beam deflector, that is, the magnetic beam deflection structure 302 overlaps up and down with the four planar Hall assemblies 301. Therefore, when a magnetic field appears parallel to the D1 direction (B//D1), the magnetic force lines FL near the edge of the magnetic beam deflection structure 302 are deflected due to the high permeability of the deflection structure itself, and the deflection generates a magnetic field component parallel to the D3 direction, which can be sensed by the planar Hall assembly 301 disposed at the edge of the magnetic beam deflection structure 302. By using simple mathematical operation, the magnetic field strength in the D1 direction can be correctly obtained, wherein the magnetic field strength parallel to the D1 direction is the difference value between the readings of the two Hall devices in FIG. 3, and the magnetic field strength parallel to the D3 direction is the sum value of the readings of the two Hall devices in FIG. 3. The deflected component in D3 direction is proportional to the magnetic field strength in the D1 direction. The magnetic field components in D1 and D2 directions parallel to the substrate plane can be obtained through the magnetic beam deflection structure 302, while the magnetic field components in D3 direction can be directly measured by all (four) planar Hall assemblies 301, and its value is the sum of the readings of four Hall device divided by four.

The disadvantage of the third prior art mentioned above is: since the magnetic field component measurement parallel to the substrate plane is realized by the magnetic field deflection generated by the magnetic beam deflection structure 302 with high permeability, the change of the magnetization state of the magnetic beam deflection structure 302 caused by the external magnetic field will directly affect the output of the planar Hall assembly 301. FIG. 4 shows a typical magnetization curve of a disk-shaped or square-plate-shaped ferromagnetic material, wherein the applied magnetic field H is parallel to the D1 direction or D2 direction (H//D1 or D2). It can be seen from FIG. 4 that when the magnetic field strength of the applied magnetic field H increases gradually, the magnetic moments in the material gradually arranged toward the positive direction of the applied magnetic field H, and approaches saturation in the high magnetic field area as the arrangement approaches completeness. When the magnetic field is removed, a residual magnetization Mᵣ is left and can be neutralized by a magnetic field in the opposite direction of the applied magnetic field H (the absolute value of magnetic field strength is H_{c}). The residual magnetization Mᵣ is a function of the applied magnetic field H, that is, it changes with the direction and intensity of the applied magnetic field. Therefore, the output of the planar Hall assembly 301 will produce a drift, which changes with the magnetization state of the magnetic beam deflection structure 302 itself. This drift will cause the inaccuracy of the measurement results in the measurement of relatively low magnetic field strength, which must be corrected at high frequency to ensure the correctness of the output results. For high field measurements, this effect is relatively small.

### The Fourth Prior Art

The three-axis Hall magnetometer provided by the fourth prior art can also be realized by at least one vertical Hall assembly 401 carried on the substrate, which can sense the magnetic field component parallel to the direction of the substrate.

FIGS. 5A-5B show the structure of a typical vertical Hall assembly, wherein the vertical Hall assembly is equivalent to a typical planar Hall assembly placed vertically. A typical vertical Hall assembly 401 has five electrodes 4011 arranged along the D1 direction parallel to the substrate, and the length of each electrode 4011 extends along the D2 direction parallel to the substrate 4012 and perpendicular to the D1 direction. In the present embodiment, each electrode 4011 is installed on a magnetic field sensing area 4013 and is installed on the substrate 4012 via the magnetic field sensing area 4013. As shown in FIG. 5B, the magnetic field sensing area 4013 of the Hall assembly is an N well, which is usually surrounded by a P well 4014, for the purpose of electrical insulation with other adjacent components. The substrate 4012 is usually a P-type substrate. The magnetic field sensing direction of the vertical Hall assembly shown in FIGS. 5A-5B is D2 direction.

FIG. 6 shows the connection mode of the vertical Hall assembly 401. The two electrodes on the outermost side are connected to each other and connected to the ground terminal Gnd, the electrode in the middle is connected to the power terminal Vdd, and the two electrodes between ground terminals Gnd and the power terminal Vdd are the first output terminal V1 and the second output terminal V2. The current flows from the power terminal to the left and right ground terminals respectively in a curved path. When the external magnetic field is zero (B=0), the current path is shown by the solid arrows CL3 in FIG. 6, wherein the paths to the left and to the right are symmetrical, so that the electric fields measured by the first output terminal V1 and the second output terminal V2 are the same, and the output of the vertical Hall assembly is zero. When an external magnetic field parallel to the D2 direction appears (B//D2), the current paths from the power terminal to the left and to the right become asymmetrical due to the effect of the Lorentz force, and the current path is shown by the dotted arrows CL4 in FIG. 6. The asymmetric current path leads to the inconsistency of the electric fields measured by the first output terminal V1 and the second output terminal V2, and thus the vertical Hall assembly generates output.

FIG. 7 shows a three-axis Hall magnetometer provided by the fourth prior art, which is realized by combining two vertical Hall assemblies 401 with a typical planar Hall assembly 402. The three-axis Hall magnetometer comprises two rectangular vertical Hall assemblies 401 and a square planar Hall assembly 402 disposed on the same surface of the substrate. Two vertical Hall assemblies 401 are disposed on the substrate and perpendicular to each other, and are respectively used to sense the magnetic field components in D1 and D2 directions. The planar Hall assembly 402 is used to sense the magnetic field component perpendicular to the direction of the substrate (i.e., the D3 direction).

The disadvantage of the fourth prior art mentioned above is: it is significantly different between the paths of currents in the planar Hall assembly 402 and the vertical Hall assembly 401. The current of the planar Hall assembly 402 is mainly parallel to the plane of the substrate, and the sensing area of the assembly extends in the plane parallel to the assembly. On the contrary, in the vertical Hall assembly 401, the current component in the direction perpendicular to the substrate is important, and the sensing area of the assembly extends in the depth direction of the substrate. Based on this difference, it is significantly different between the optimization conditions of the N well in the manufacturing process on the planar Hall assemblies and vertical Hall assemblies 401. As for planar Hall assemblies, a relatively shallow well will help to improve the sensitivity. As for the vertical Hall assemblies 401, the sensitivity is proportional to the depth of the N well. It is an inevitable difficulty in the implementation of this design to integrate two different N-wells in the same manufacturing process.

In summary, the existing three-axis magnetic sensing technology has the following disadvantages: small range, complex process, poor resistance to magnetic interference, and high production cost.

### SUMMARY

The present application aims to provide a three-axis Hall magnetometer to expand the range, simplify the process, improve the resistance to magnetic interference and reduce the production cost.

Thus, the technical solution of the present application is to provide a three-axis Hall magnetometer, which is integrated on a single substrate, and comprises at least one magnetic beam deflection structure located on a first plane and a plurality of vertical Hall assemblies located on a second plane parallel to the first plane, and do not comprise any planar Hall assembly. Each magnetic beam deflection structure is in an elongated shape with two parallel long sides and a length-width ratio greater than 2. The magnetic beam deflection structure comprises at least one first-type magnetic beam deflection structure which extends in a first direction on the first plane. Each vertical Hall assembly comprises 5 electrodes extending along the sensing direction of the vertical Hall assembly, and the sensing direction of each vertical Hall assembly is parallel to the first plane. The plurality of vertical Hall assemblies comprise at least one first-type vertical Hall assembly and at least one second-type vertical Hall assembly, each of which is located near one long side of the first-type magnetic beam deflection structure and has a sensing direction perpendicular to the long side of the first-type magnetic beam deflection structure. The first-type vertical Hall assembly is located on a first side of its nearby first-type magnetic beam deflection structure and the second-type vertical Hall assembly is located on a second side of its nearby first-type magnetic beam deflection structure, wherein the first side and the second side of the first-type magnetic beam deflection structure are two opposite sides on which the long sides of the first-type magnetic beam deflection structure are located. And the plurality of vertical Hall assemblies further comprise at least one third-type vertical Hall assembly which has a sensing direction different from those of the first-type vertical Hall assembly and the second-type vertical Hall assembly.

The magnetic beam deflection structure also comprises at least one second-type magnetic beam deflection structure, the long axis of each of which extends along a second direction different from the first direction on the first plane; the plurality of vertical Hall assemblies also comprise at least one fourth-type vertical Hall assembly, wherein each of the third-type vertical Hall assembly and the fourth-type vertical Hall assembly is located near one long side of the second-type magnetic beam deflection structure and has a sensing direction perpendicular to the long side of the second-type magnetic beam deflection structure; and the third-type vertical Hall assembly is located on a first side of its nearby second-type magnetic beam deflection structure and the fourth-type vertical Hall assembly is located on a second side of its nearby second-type magnetic beam deflection structure, wherein the first side and the second side of the second-type magnetic beam deflection structure are two opposite sides on which the long sides of the second-type magnetic beam deflection structure are located.

The magnetic beam deflection structure is composed of a magnetic material with high permeability, and the relative permeability of the magnetic material is higher than 100.

Each vertical Hall assembly is separated from its nearby magnetic beam deflection structure in the vertical direction by an electrical insulating layer, and every two vertical Hall assemblies are separated from each other in a direction on the second plane.

The first direction and the second direction are perpendicular to each other.

The number of the first-type magnetic beam deflection structures and the number of the second-type magnetic beam deflection structures are both two, wherein the first-type vertical Hall assembly is located on the first side of one of two first-type magnetic beam deflection structures, the second-type vertical Hall assembly is located on the second side of the other one of two first-type magnetic beam deflection structures, the third-type vertical Hall assembly is located on the first side of one of two second-type magnetic beam deflection structures, and the fourth-type vertical Hall assembly is located on the second side of the other one of two second-type magnetic beam deflection structures.

The number of the third-type vertical Hall assemblies and the number of the fourth-type vertical Hall assemblies are both multiple, wherein the third-type vertical Hall assemblies are arranged along the long side on the first side of the second-type magnetic beam deflection structure(s), and the fourth-type vertical Hall assemblies are arranged along the long side on the second side of the second-type magnetic beam deflection structure(s).

There are an even number of vertical Hall assemblies coupled and connected among the third-type vertical Hall assemblies or fourth-type vertical Hall assemblies; or, at least one of the third-type vertical Hall assemblies and at least one of the fourth-type vertical Hall assemblies are coupled and connected as a group, and another at least one of the third-type vertical Hall assemblies and another at least one of the fourth-type vertical Hall assemblies are also coupled and connected as a group, wherein the numbers of the third-type vertical Hall assemblies and the fourth-type vertical Hall assemblies coupled and connected in each group are equal.

The number of the first-type vertical Hall assemblies and the number of the second-type vertical Hall assemblies are both multiple, wherein the first-type vertical Hall assemblies are arranged along the long side on the first side of the first-type magnetic beam deflection structure, and the second-type vertical Hall assemblies are arranged along the long side on the second side of the first-type magnetic beam deflection structure.

There are an even number of vertical Hall assemblies coupled and connected among the first-type vertical Hall assemblies or the second-type vertical Hall assemblies; or, at least one of the first-type vertical Hall assemblies and at least one of the second-type vertical Hall assemblies are coupled and connected as a group, and another at least one of the first-type vertical Hall assemblies and another at least one of the second-type vertical Hall assemblies are also coupled and connected as a group, wherein the numbers of the first-type vertical Hall assemblies and the second-type vertical Hall assemblies coupled and connected in each group are equal.

The three-axis Hall magnetometer of the present application has the following advantages:
(1) The three-axis Hall magnetometer of the present application only comprises the vertical Hall assemblies and does not comprise any planar Hall assembly. Therefore, there is only one N-well that needs to be optimized when optimizing the Hall assembly. Compared with the magnetometer composed of the planar and the vertical Hall assemblies, the manufacturing complexity is much lower, and the process is simplified.
(2) The three-axis Hall magnetometer of the present application is integrated on a single substrate, so it can be integrated into a single chip and can support single-chip packaging, which leads to low production cost.
(3) The magnetic beam deflection structure of the three-axis Hall magnetometer of the present application has long sides and a length-width ratio greater than 2, and its sensing direction is perpendicular to the long side, so the magnetic hysteresis in the sensing direction of it is significantly lower than that of the traditional magnetic beam deflection structure with a plane structure (quasi two-dimensional), and thus the three-axis Hall magnetometer of the present application has better performance in resistance to strong magnetic interference in the application of low magnetic field sensing.
(4) The magnetic beam deflection structure of the three-axis Hall magnetometer of the present application has long sides and a length-width ratio greater than 2, and the magnetization saturation field in the width direction of it is far greater than that of the traditional magnetic beam deflection structure with a plane structure (quasi two-dimensional), so the working range of the magnetometer of the present application is significantly greater than that of the magnetometer based on the magnetic beam deflection structure with a plane structure.

### BRIEF DESCRIPTION OF THE DRAWINGS

These and other features and advantages of this application will become more apparent to those skilled in the art from the detailed description of preferred embodiment. The drawings that accompany the description are described below. Wherein, FIG. 1 is a structural schematic diagram of a typical planar Hall assembly for magnetic field sensing.

FIG. 2 is a top-view diagram of the three-axis Hall magnetometer realized by the magnetic beam deflection structure provided by the third prior art.

FIG. 3 is a schematic cross-sectional view along the line A-A in FIG. 2.

FIG. 4 is a typical magnetization curve diagram of a disk-shaped or square-plate-shaped ferromagnetic material.

FIGS. 5A-5B are structural schematic diagrams of a typical vertical Hall assembly, wherein FIG. 5A is a top view, and FIG. 5B is a schematic cross-sectional view along the line A-A in FIG. 5A.

FIG. 6 is a diagram of the current path in a vertical Hall assembly.

FIG. 7 is a structural schematic diagram of a three-axis Hall magnetometer composed of a planar Hall assembly and two vertical Hall assemblies.

FIG. 8 is a structural schematic diagram of a three-axis Hall magnetometer according to the first embodiment of the present application.

FIG. 9 is a schematic cross-sectional view along the line B-B in FIG. 8.

FIG. 10 is a schematic diagram of coupling and connection of two vertical Hall assemblies according to an embodiment of the present application.

FIG. 11A-FIG. 11B are schematic diagrams of magnetic field lines near the magnetic beam deflection structure of the three-axis Hall magnetometer as shown in FIG. 8, wherein FIG. 11A shows the case where the applied magnetic field is parallel to the second direction, and FIG. 11B shows the case where the applied magnetic field is parallel to the third direction.

FIG. 12A-FIG. 12B are principal diagrams of the measurement method of the magnetic field components along three axes realized by the three-axis Hall magnetometer of the present application.

FIG. 13 is a diagram of a typical magnetization curve of a magnetic beam deflection structure in an elongated shape along its width direction.

FIG. 14 is a structural schematic diagram of a three-axis Hall magnetometer according to the second embodiment of the present application.

FIG. 15 is a structural schematic diagram of a three-axis Hall magnetometer according to the third embodiment of the present application.

FIG. 16 is a structural schematic diagram of a three-axis Hall magnetometer according to the fourth embodiment of the present application.

FIG. 17 is a schematic cross-sectional view along the line C-C in FIG. 16.

FIG. 18 is a structural schematic diagram of a three-axis Hall magnetometer according to the fifth embodiment of the present application.

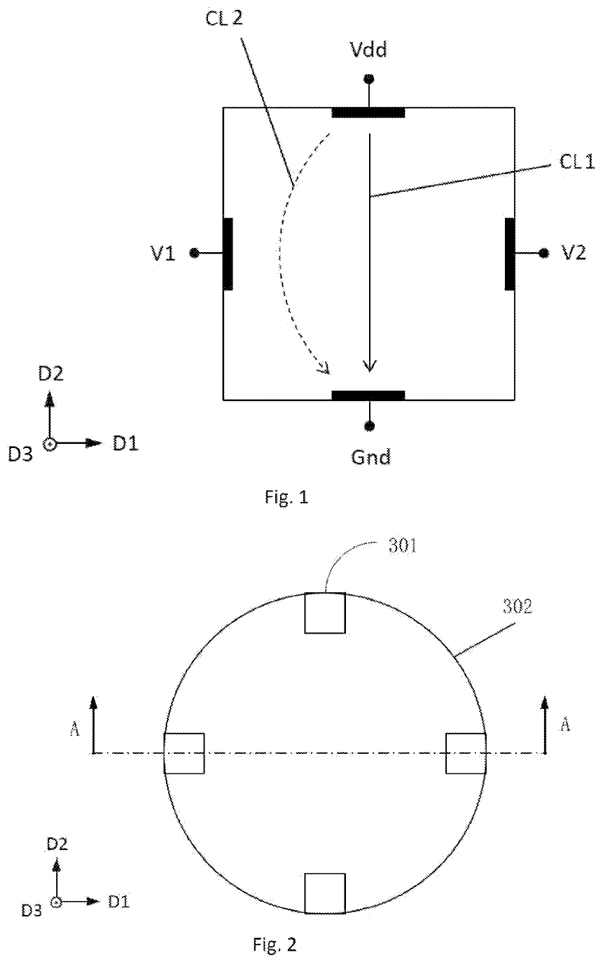

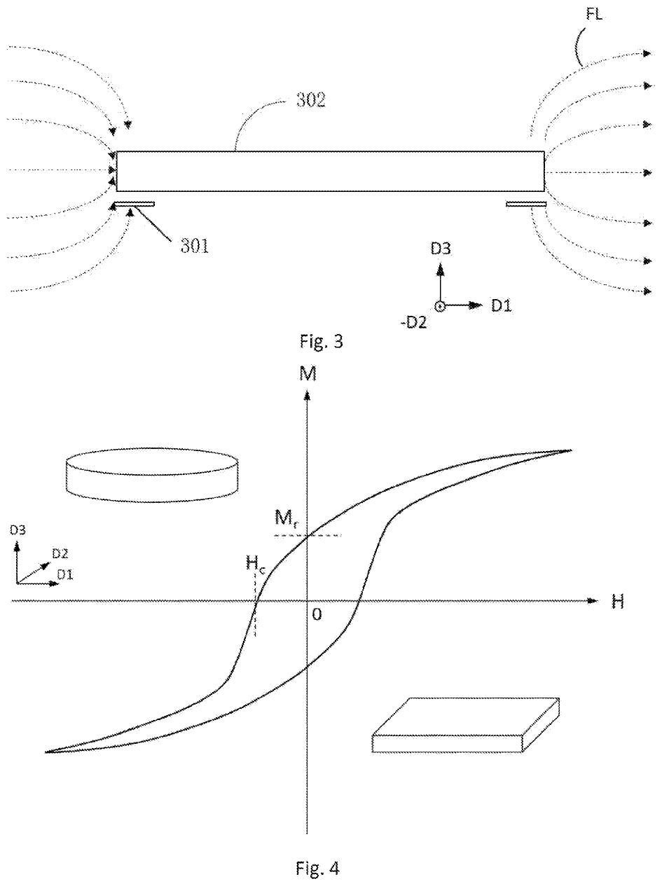

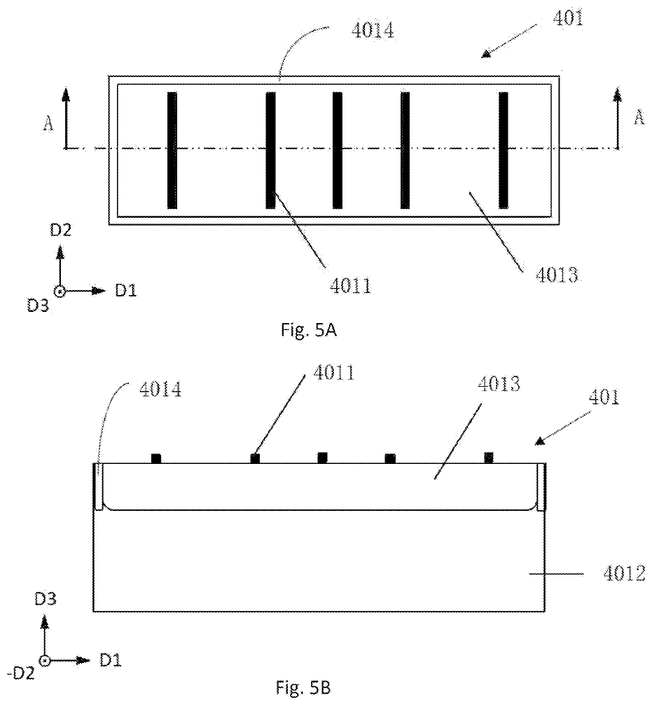

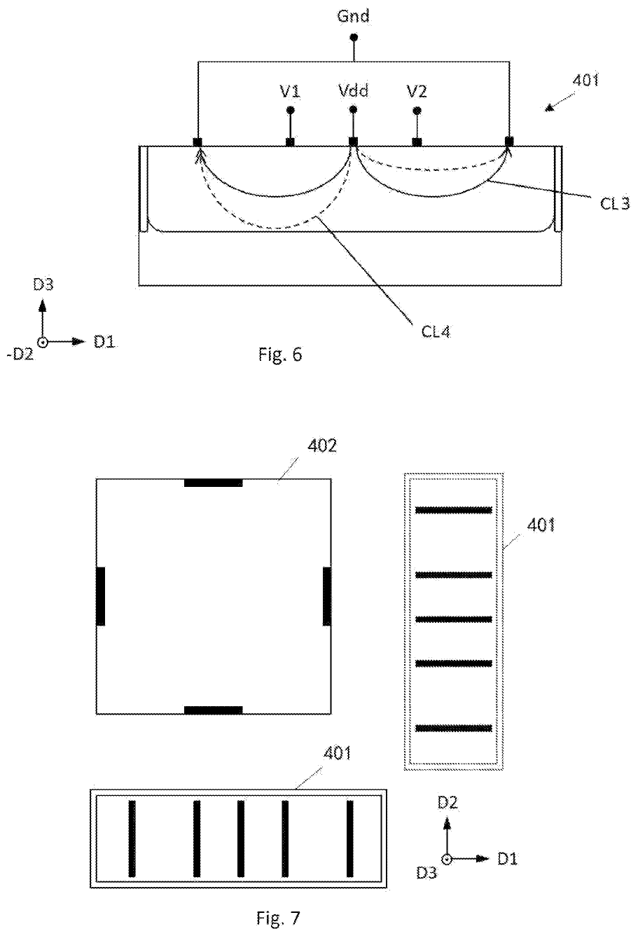

### DETAILED DESCRIPTION

The embodiments of the present application are described in detail below. The embodiments are implemented on the premise of the technical solution of the present application, and detailed implementation methods are given. However, the protection scope of the present application is not limited to the following embodiments.

The present application provides a three-axis Hall magnetometer, which is integrated on a single substrate and does not need to comprise any planar Hall assembly. The three-axis Hall magnetometer comprises at least one magnetic beam deflection structure on a first plane and a plurality of vertical Hall assemblies located on a second plane parallel to the first plane.

Wherein, each magnetic beam deflection structure is in an elongated shape with two parallel long sides and a large length-width ratio, wherein the length-width ratio of the magnetic beam deflection structure is greater than 2. The magnetic beam deflection structure is composed of magnetic materials with high permeability, and the relative permeability of magnetic materials is higher than 100. In the present embodiment, the elongated shape of the magnetic beam deflection structure is greater than 30 μm in length and is greater than 3 μm in width.

Each vertical Hall assembly comprises five electrodes extending along the sensing direction of the vertical Hall assembly, and the sensing direction of each vertical Hall assembly is parallel to the first plane of the substrate. At least one vertical Hall assembly is disposed near the long sides of each magnetic beam deflection structure, and each vertical Hall assembly is located near at most one magnetic beam deflection structure, so that the magnetic field component deflected by the magnetic beam deflection structure can be sensed by the vertical Hall assembly near it. The magnetic beam deflection structure comprises at least one first-type magnetic beam deflection structure extending along the first direction of the first plane, and each of the first-type vertical Hall assembly and the second-type vertical Hall assembly is located near one long side of the first-type magnetic beam deflection structure and has a sensing direction perpendicular to the long side of the first-type magnetic beam deflection structure. And the first-type vertical Hall assembly and the second-type vertical Hall assembly are located at the first side and the second side of their nearby first-type magnetic beam deflection structure(s) respectively. The first side and the second side of a first-type magnetic beam deflection structure are two opposite sides on which the long sides of the first-type magnetic beam deflection structure are located. The magnetic field component perpendicular to the plane of the substrate is sensed by a plurality of vertical Hall assemblies due to the deflection of the magnetic beam deflection structure.

A plurality of vertical Hall assemblies also comprises at least one third-type vertical Hall assembly whose sensing direction is different from those of the first-type vertical Hall assembly and the second-type vertical Hall assembly. Therefore, the first-type vertical Hall assembly and the second-type vertical Hall assembly are obliquely or vertically disposed relative to the third type vertical Hall assembly on the same substrate, and the magnetic field component parallel to the plane of the substrate can be directly sensed by a plurality of vertical Hall assemblies that are obliquely or vertically disposed relative to each other.

When there are multiple first-type vertical Hall assemblies or multiple second-type vertical Hall assemblies, the first-type vertical Hall assemblies or second-type vertical Hall assemblies are arranged along the extension direction of the magnetic beam deflection structure.

In addition, the magnetic beam deflection structure can also comprise at least one second-type magnetic beam deflection structure. The long axes of each second-type magnetic beam deflection structure extend along a second direction different from the first direction on the first plane. In this case, a plurality of vertical Hall assemblies comprise not only at least one third-type vertical Hall assembly with a sensing direction different from that of the first type vertical Hall assembly and the second type vertical Hall assembly, but also a fourth-type vertical Hall assembly with the same sensing direction as that of the third type vertical Hall assembly. Each of the third-type vertical Hall assembly and the fourth-type vertical Hall assembly is located near one long side of the second-type magnetic beam deflection structure and has a sensing direction perpendicular to the long side of the second-type magnetic beam deflection structure. The third-type vertical Hall assembly and the fourth-type vertical Hall assembly are located at the first side and the second side of their nearby second-type magnetic beam deflection structure(s) respectively. The first side and the second side of a second-type magnetic beam deflection structure are two opposite sides on which the long sides of the second-type magnetic beam deflection structure are located.

### The First Embodiment Three-Axis Hall Magnetometer

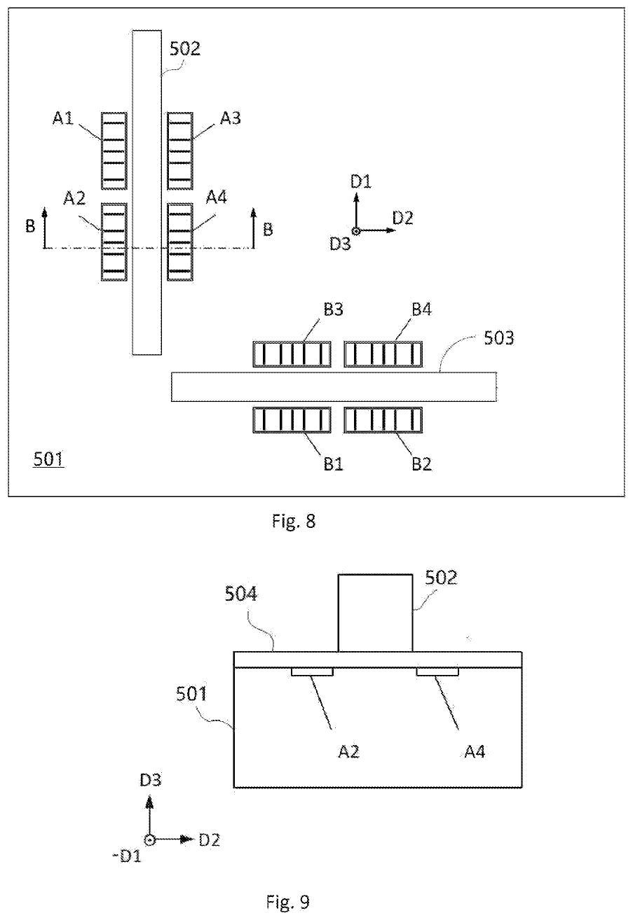

As shown in FIG. 8, the three-axis Hall magnetometer according to the first embodiment of the present application is composed of a substrate 501 located on the first plane, two magnetic beam deflection structures and a plurality of vertical Hall assemblies fixed on the substrate 501.

Wherein, the magnetic beam deflection structure can be independent of the substrate 501 and fixed on the upper surface of the substrate 501, or can be grown (such as electroplated) on the upper surface of the substrate 501 and formed integrally therewith. Each magnetic beam deflection structure is in an elongated shape and has a large length-width ratio which is greater than 2. Two magnetic beam deflection structures are located on the same plane, comprising a first-type magnetic beam deflection structure 502 and a second-type magnetic beam deflection structure 503. In the present embodiment, the first-type magnetic beam deflection structure 502 extends along the first direction D1 on the first plane, and the second-type magnetic beam deflection structure 503 extends along the second direction D2 on the first plane. In the present embodiment, the first direction D1 and the second direction D2 are perpendicular to each other. Among the relative relationships between the first-type magnetic beam deflection structure 502 and the second-type magnetic beam deflection structure 503, the angle between their long axes is important, rather than the relative position between them, so there is a relatively large degree of freedom in the arrangement. The combination of the first-type magnetic beam deflection structure 502 and the second-type magnetic beam deflection structure 503 may be L-shaped, T-shaped or in any other shape.

The vertical Hall device can be embedded in the substrate as part of the substrate, or can be independent of the substrate 501 and fixed on the upper surface of the substrate 501.

The vertical Hall assemblies comprise at least one first-type vertical Hall assembly A1, A2 and at least one second-type vertical Hall assembly A3, A4 disposed near the first-type magnetic beam deflection structure 502. Each of the first-type vertical Hall assemblies A1, A2 and the second-type vertical Hall assemblies A3, A4 has the same sensing direction which is perpendicular to the extension direction of the first-type magnetic beam deflection structure 502, namely, the second direction D2 perpendicular to the first direction D1 on the first plane. Each electrode of the first-type vertical Hall assemblies A1, A2 and the second-type vertical Hall assemblies A3, A4 extends along the second direction D2, so it can be used to measure the magnetic field in the second direction D2. In addition, the first-type vertical Hall assemblies A1, A2 and the second-type vertical Hall assemblies A3, A4 are located on the first side and the second side of their nearby first-type magnetic beam deflection structure 502 respectively. The first side and the second side are the two opposite sides on which the long sides of the first-type magnetic beam deflection structure 502 are located. In the present embodiment, the number of first-type vertical Hall assemblies A1, A2 is 2, and the number of second-type vertical Hall assemblies A3, A4 is 2. The first-type vertical Hall assemblies A1, A2 are arranged along the long side located on the first side of the first-type magnetic beam deflection structure 502, and the second-type vertical Hall assemblies A3, A4 are arranged along the long side located on the second side of the first-type magnetic beam deflection structure 502.

In addition, the vertical Hall assemblies also comprise at least one third-type vertical Hall assembly B1, B2 and at least one fourth-type vertical Hall assembly B3, B4 disposed near the second-type magnetic beam deflection structure 503. Each of the third-type vertical Hall assemblies B1, B2 and the fourth-type vertical Hall assemblies B3, B4 has the same sensing direction which is perpendicular to the extension direction of the second-type magnetic beam deflection structure 503, that is, the first direction D1 on the first plane. Each electrode of the third-type vertical Hall assemblies B1, B2 and the fourth-type vertical Hall assemblies B3, B4 is parallel to the first direction D1. The third-type vertical Hall assemblies B1, B2 and the fourth-type vertical Hall assemblies B3, B4 are located on the first side and the second side of their nearby second-type magnetic beam deflection structure 503, respectively. The first side and the second side of the second-type magnetic beam deflection structure 503 are two opposite sides on which the long sides of the second-type magnetic beam deflection structure 503 are located. In the present embodiment, the number of third-type vertical Hall assemblies B1, B2 is 2, and the number of fourth-type vertical Hall assemblies B3, B4 is 2. In other embodiments, the number of third-type vertical Hall assemblies and the number of fourth-type vertical Hall assemblies B3, B4 can also be any other number. The third-type vertical Hall assemblies B1, B2 are arranged along the long side located on the first side of the second-type magnetic beam deflection structure 503, and the fourth-type vertical Hall assemblies B3, B4 are arranged along the long side located on the second-type magnetic beam deflection structure 503.

FIG. 9 shows the cross-section along the line B-B in FIG. 8, which shows that the first-type vertical Hall assembly A2 and the second-type vertical Hall assembly A4 are located below the first-type magnetic beam deflection structure 502 (similarly, the first-type vertical Hall assembly A1 and the second-type vertical Hall assembly A3 are also located below the first-type magnetic beam deflection structure 502). In the present embodiment, the first-type vertical Hall assembly A2 and the second-type vertical Hall assembly A4 are separated from their nearby magnetic beam deflection structure in the vertical direction by an electrical insulating layer 504 respectively. Similarly, each vertical Hall assembly is separated from its nearby magnetic beam deflection structure in the vertical direction by an electrical insulating layer. Each vertical Hall assembly A1, A2, A3, A4 can overlap up and down (or not overlap up and down) with its nearby magnetic beam deflection structure, but every two vertical Hall assemblies A1, A2, A3, A4 are separated from each other in the direction of the second plane, with the separation distance of more than one micron (μm).

Similarly, the third-type vertical Hall assemblies B1, B2 and the fourth-type vertical Hall assemblies B3, B4 are located below the second-type magnetic beam deflection structure 503. Each of the third-type vertical Hall assemblies B1, B2 and the fourth-type vertical Hall assemblies B3, B4 is separated from its nearby magnetic beam deflection structure in the vertical direction by an electrical insulating layer. Each of the third-type vertical Hall assemblies B1, B2 and the fourth-type vertical Hall assemblies B3, B4 can overlap up and down with its nearby magnetic beam deflection structure, but every two vertical Hall assemblies B1, B2, B3, B4 are separated from each other, with the separation distance of more than one micron (μm).

There may be an even number of vertical Hall assemblies (such as, A1, A2) coupled and connected among the first-type vertical Hall assemblies A1, A2 or the second-type vertical Hall assemblies A3, A4 to form a single sensing assembly. That is to say, a single sensing assembly may be composed of an even number of first-type vertical Hall assemblies A1, A2 or an even number of second-type vertical Hall assemblies A3, A4 coupled and connected. Alternatively, at least one of the first-type vertical Hall assemblies A1, A2 may be coupled and connected with at least one of the second-type vertical Hall assemblies A3, A4 (such as, A1 and A3, or A1 and A4) to form a single sensing assembly. In the embodiment shown in FIG. 8, at least one of the first-type vertical Hall assemblies A1, A2 and at least one of the second-type vertical Hall assemblies A3, A4 (such as, A1 and A3, or A1 and A4) are coupled and connected as a group, and the resulting sensing assembly can only generate an output of the magnetic field in a single direction (comprising an output of the parallel magnetic field or antiparallel magnetic field of the two vertical Hall assemblies), and another at least one of the first-type vertical Hall assemblies A1, A2 and another at least one of the second-type vertical Hall assemblies A3, A4 are also coupled and connected as a group, so as to produce an output of the magnetic field in another direction, wherein the numbers of first-type vertical Hall assemblies and second-type vertical Hall assemblies coupled and connected in each group are equal. In the present embodiment, the numbers of the first-type vertical Hall assemblies and second-type vertical Hall assemblies coupled and connected in each group are both 1.

In other embodiments, there is no coupling relationship between any two vertical Hall assemblies among the first-type vertical Hall assemblies A1, A2 and the second-type vertical Hall assemblies A3, A4, so that the vertical Hall assemblies work as independent devices. It should be noted that, if there is no coupling relationship between any two vertical Hall assemblies among the first vertical Hall assemblies A1, A2 and the second vertical Hall assemblies A3, A4, only one first-type vertical Hall assembly and only one second-type vertical Hall assembly can be used to obtain the outputs of the parallel magnetic field and antiparallel magnetic field of the first-type vertical Hall assembly and the second-type vertical Hall assembly by the measurement method below shown in FIGS. 12A-12B, and further the external magnetic field components parallel to the second direction D2 and the third direction D3 can be obtained. Otherwise, at least two first-type vertical Hall assemblies A1, A2 and at least two second-type vertical Hall assemblies A3, A4 are required to couple and connect to obtain the outputs of parallel magnetic field and antiparallel magnetic field of the first-type vertical Hall assembly and the second-type vertical Hall assembly respectively, and further the external magnetic field components parallel to the second direction D2 and the third direction D3 can be obtained.

Similarly, there is no coupling relationship between any two vertical Hall assemblies among the third-type vertical Hall assemblies B1, B2 and the fourth-type vertical Hall assemblies B3, B4, so that the vertical Hall assemblies work as independent devices. Alternatively, there may be an even number of vertical Hall assemblies (such as B1, B2) coupled and connected among the third-type vertical Hall assemblies B1, B2 or the fourth-type vertical Hall assemblies B3, B4 to form a single sensing assembly. In addition, at least one of the third-type vertical Hall assemblies B1, B2 may be coupled and connected with at least one of the fourth-type vertical Hall assemblies B3, B4 (such as, B1 and B3, or B1 and B4) to form a single sensing assembly.

The output of the sensing assembly obtained by coupling and connecting multiple vertical Hall assemblies is the mean value of the signals of multiple vertical Hall assemblies. A main function of the coupling and connecting the vertical Hall assemblies is to reduce the output drift of the assemblies under zero magnetic fields.

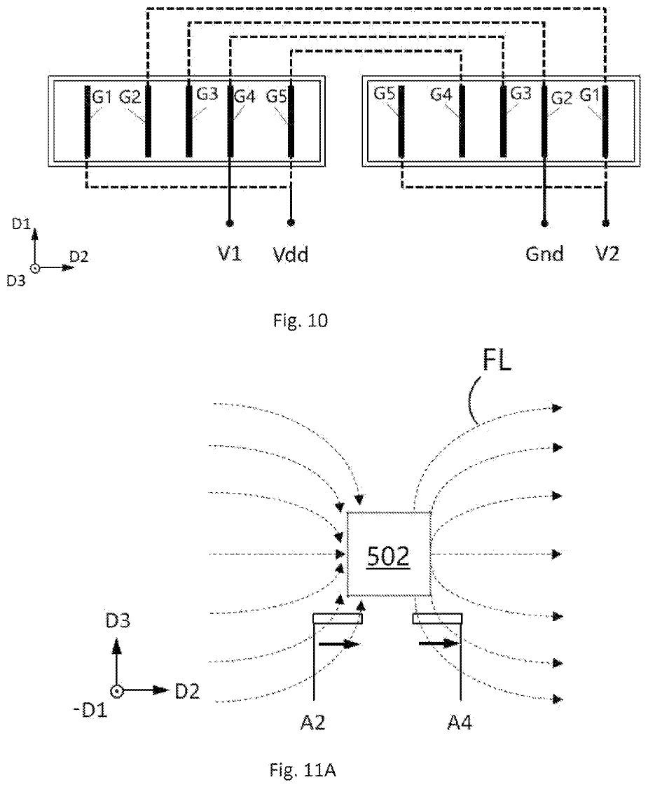

The number of vertical Hall assemblies coupled and connected is usually a multiple of 2 or a multiple of 4. FIG. 10 shows an exemplary schematic diagram of coupling and connection of two vertical Hall assemblies according to an embodiment of the present application. Each vertical Hall assembly comprises a first electrode G1, a second electrode G2, a third electrode G3, a fourth electrode G4 and a fifth electrode G5 arranged in one direction. Wherein, the first electrode G1 and the fifth electrode G5 of the first vertical Hall assembly are connected with the fourth electrode G4 of the second vertical Hall assembly, and they are all connected with the power terminal Vdd. The second electrode G2 of the first vertical Hall assembly is connected with the first electrode G1 and the fifth electrode G5 of the second vertical Hall assembly, and they are all connected with the second output terminal V2. The third electrode G3 of the first vertical Hall assembly is connected with the second electrode G2 of the second vertical Hall assembly and they are both connected with the ground terminal Gnd. The fourth electrode G4 of the first vertical Hall assembly is connected with the third electrode G3 of the second vertical Hall assembly and they are both connected with the first output terminal V1.

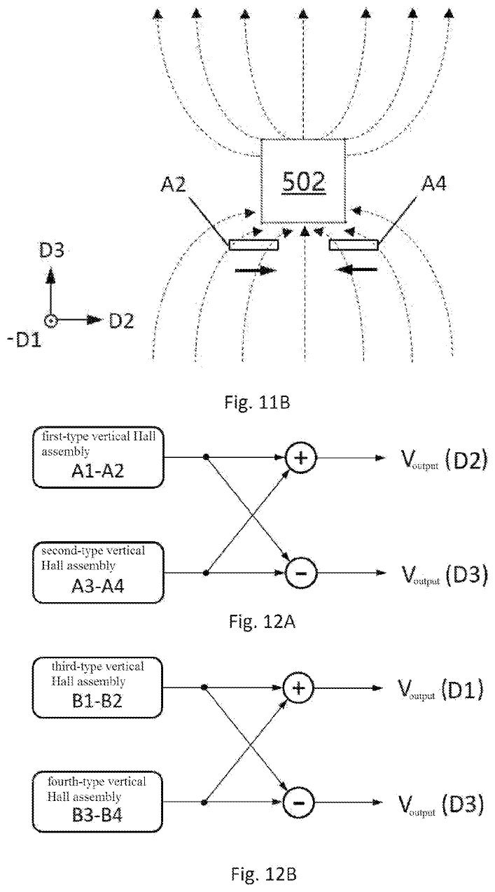

The working principle of the three-axis Hall magnetometer of the present application is described in detail below in combination with FIGS. 11A-13.

As shown in FIG. 11A, when the three-axis Hall magnetometer of the present application is exposed to an external magnetic field parallel to the second direction D2 (B//D2), the magnetic lines FL near the first-type magnetic beam deflection structure 502 will be deflected towards the direction of the first-type magnetic beam deflection structure 502, as shown by the dotted arrows in FIG. 11A. The deflection generates the magnetic field components of the second direction D2 and the third direction D3 (the third direction D3 is perpendicular to the first plane) at the first vertical Hall assembly A2 and the second vertical Hall assembly A4, wherein the magnetic field components parallel to the second direction D2 as shown by the solid arrows will be sensed by the first vertical Hall assembly A2 and the second vertical Hall assembly A4. In the example shown in FIG. 11A, the first-type vertical Hall assembly A2 and the second-type vertical Hall assembly A4 sense the parallel magnetic fields of the first-type vertical Hall assembly and the second-type vertical Hall assembly, that is, the magnetic fields with same strength and parallel to the second direction D2.

As shown in FIG. 11B, when the three-axis Hall magnetometer of the present application is exposed to an external magnetic field parallel to the third direction D3 (B//D3), the magnetic lines FL near the first-type magnetic beam deflection structure 502 will be deflected towards the direction of the first-type magnetic beam deflection structure 502, as shown by the dotted arrows in FIG. 11B. The deflection generates the magnetic field components in the second direction D2 and the third direction D3 at the first vertical Hall assembly A2 and the second vertical Hall assembly A4, wherein the magnetic field components parallel to the second direction D2 as shown by the solid arrows will be sensed by the first vertical Hall assembly A2 and the second vertical Hall assembly A4. In the example shown in FIG. 11B, the first vertical Hall assembly A2 sense the magnetic field parallel to the second direction D2, the second-type vertical Hall assembly A4 sense the magnetic field antiparallel to the second direction D2, and the first-type vertical Hall assembly A2 and the second-type vertical Hall assembly A4 sense the antiparallel magnetic fields of the first-type vertical Hall assembly and the second-type vertical Hall assembly, that is, the magnetic fields sensed by the first-type vertical Hall assembly A2 and the second-type vertical Hall assembly A4 are in the opposite directions but has the same intensity absolute value.

FIGS. 12A-12B show the measurement method of the magnetic field components along three axes (i.e. the three directions D1, D2, and D3) realized by the three-axis Hall magnetometer of the present application.

As shown in FIG. 12A and described above, when the applied magnetic field is parallel to the second direction D2, the first-type vertical Hall assemblies A1, A2 and the second-type vertical Hall assemblies A3, A4 have the same output. When the applied magnetic field is parallel to the third direction D3, the first-type vertical Hall assemblies A1, A2 have the same output, and the outputs of second-type vertical Hall assemblies A3, A4 and the outputs of the first-type vertical Hall assemblies A1, A2 are the same in strength and opposite in direction. Therefore, the strength of the parallel magnetic field of the first-type vertical Hall assemblies A1, A2 and the second-type vertical Hall assemblies A3, A4 is the magnetic field strength parallel to the second direction D2, which is obtained by adding the outputs of the first-type vertical Hall assemblies A1, A2 and the second-type vertical Hall assemblies A3, A4, and calculating the mean value (that is, dividing the sum of the outputs by the total number of the first-type vertical Hall assemblies A1, A2 and the second-type vertical Hall assemblies A3, A4), and the magnetic field components in the third direction D3 will be offset. The strength of the antiparallel magnetic field of the first-type vertical Hall assemblies A1, A2 and the second-type vertical Hall assemblies A3, A4 is the magnetic field strength parallel to the third direction D3, which is obtained by subtracting the sum of the outputs of the first-type vertical Hall assemblies A1, A2 from the sum of the outputs of the second-type vertical Hall assemblies A3, A4, and calculating the mean value (that is, dividing the difference between two sums of outputs by the total number of the first-type vertical Hall assemblies A1, A2 and the second-type vertical Hall assemblies A3, A4), and the magnetic field components in the second direction D2 will be offset.

Therefore, the external magnetic field components parallel to the second direction D2 and the third direction D3 are sensed and output by the first-type vertical Hall assemblies and the second-type vertical Hall assemblies.

As shown in FIG. 12B, when the applied magnetic field is parallel to the first direction D1, the third-type vertical Hall assemblies B1, B2 and the fourth-type vertical Hall assemblies B3, B4 have the same output. When the applied magnetic field is parallel to the third direction D3, the third-type vertical Hall assemblies B1, B2 have the same output, and the outputs of the fourth-type vertical Hall assemblies B3, B4 and the outputs of the third-type vertical Hall assemblies B1, B2 are the same in strength and opposite in direction. Therefore, the strength of the parallel magnetic field of the third-type vertical Hall assemblies B1, B2 and the fourth-type vertical Hall assemblies B3, B4 is the magnetic field strength parallel to the first direction D1, which can be obtained by adding the outputs of the third-type vertical Hall assemblies B1, B2 and the fourth-type vertical Hall assemblies B3, B4 and calculating the mean value, and the magnetic field components in the third direction D3 will be offset. The strength of the antiparallel magnetic field of the third-type vertical Hall assemblies B1, B2 and the fourth-type vertical Hall assemblies B3, B4 is the strength of the magnetic field in the third direction D3, which can be obtained by subtracting the sum of the outputs of the third-type vertical Hall assemblies B1, B2 from the sum of the outputs of the fourth-type vertical Hall assemblies B3, B4 and calculating the mean value, and the magnetic field components in the first direction D1 will be offset.

Therefore, the external magnetic field components parallel to the first direction D1 and the third direction D3 are sensed and output by the third-type vertical Hall assemblies and the fourth-type vertical Hall assemblies.

The three-axis Hall magnetometer of the present application has the following two special advantages in performance: (1) extremely low magnetic hysteresis phenomenon, and (2) large working range.

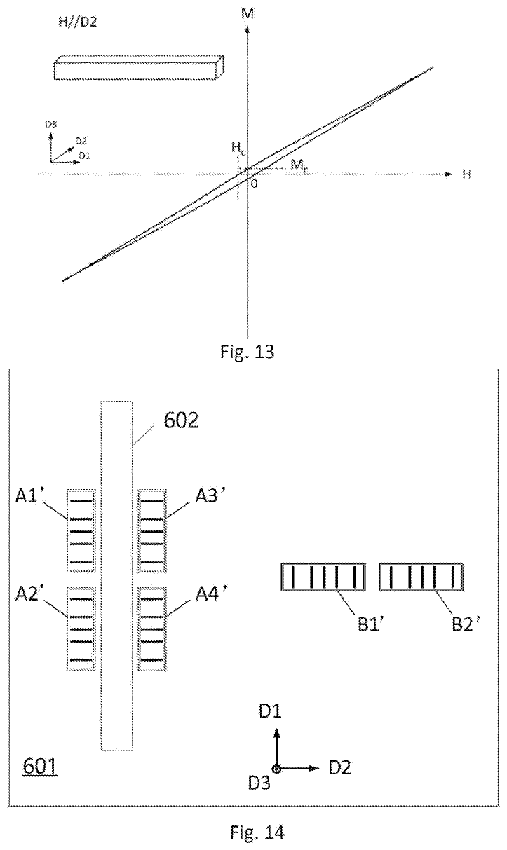

FIG. 13 is a typical magnetization curve of an elongated magnetic beam deflection structure with a large aspect ratio in the three-axis Hall magnetometer of the present application. The magnetization curve records the change of the magnetic moment of the material itself of the magnetic beam deflection structure in the direction of its short axis when the external magnetic field increases from the minimum value (that is, maximum negative field) to the maximum value (that is, maximum positive field) and then returns to the minimum value. Compared with the magnetization curve of the planar magnetic beam deflection structure (as shown in FIG. 4), the area enclosed by the magnetization curve of the elongated magnetic beam deflection structure in the present application is significantly smaller, which leads to significantly smaller residual magnetization and coercive force, and significantly higher magnetization saturation field.

Therefore, the magnetic beam deflection structure adopted by the present application improves the resistance to external strong magnetic field interference of the magnetometer designed by it due to its low magnetic hysteresis phenomenon, and improves the accuracy of the output of the three-axis Hall magnetometer of the present application under magnetic interference, which is particularly obvious in the measurements of low magnetic fields.

The magnetic beam deflection structure of the present application has a relatively high saturation magnetic field in the width direction, which provides the three-axis Hall magnetometer of the present application with a higher working range. This feature has obvious advantages in strong magnetic field measurement applications, such as angle detection applications using permanent magnets because once the beam deflection structure approaches the magnetization saturation state, its permeability will be significantly reduced and the deflection effect on the adjacent magnetic field will be sharply weakened, resulting in the loss of sensitivity of the magnetometer that measures the output of the deflection field.

### The Second Embodiment Three-Axis Hall Magnetometer

As shown in FIG. 14, a three-axis Hall magnetometer according to the second embodiment of the present application is composed of a substrate 601 located on the first plane, and a magnetic beam deflection structure and a plurality of vertical Hall assemblies fixed on the substrate 601.

Wherein, each magnetic beam deflection structure is in an elongated shape and has a large length-width ratio which is greater than 2. In the present embodiment, the magnetic beam deflection structure is the first-type magnetic beam deflection structure 602, and the first-type magnetic beam deflection structure 502 extends along the first direction D1 on the first plane.

The vertical Hall assembly comprises at least one first-type vertical Hall assembly A1′, A2′ and at least one second-type vertical Hall assembly A3′, A4′ disposed near the first-type magnetic beam deflection structure 602. Each of the first-type vertical Hall assemblies A1′, A2′ and the second-type vertical Hall assemblies A3′, A4′ has the same sensing direction which is perpendicular to the extension direction of the first-type magnetic beam deflection structure 602, that is, the second direction D2 perpendicular to the first direction D1 on the first plane. And the first-type vertical Hall assemblies A1 ‘, A2’ and the second-type vertical Hall assemblies A3′, A4′ are located on the first side and the second side of their nearby first-type magnetic beam deflection structure 602 respectively. The first side and the second side are the two opposite sides on which the long sides of the first-type magnetic beam deflection structure 602 are located. In the present embodiment, the number of first-type vertical Hall assemblies A1′, A2′ is 2, and the number of second-type vertical Hall assemblies A3′, A4′ is 2. The first-type vertical Hall assemblies A1′, A2′ are arranged along the long side located on the first side of the first-type magnetic beam deflection structure 602, and the second-type vertical Hall assemblies A3′, A4′ are arranged along the long side located on the second side of the first-type magnetic beam deflection structure 602. As shown in FIG. 14, each electrode of the first-type vertical Hall assemblies A1′, A2′ and the second-type vertical Hall assemblies A3′, A4′ extends along the second direction D2, so it can be used to measure the magnetic field in the second direction D2.

There may be an even number of vertical Hall assemblies (such as, A1′, A2′) coupled and connected among the first-type vertical Hall assemblies A1′, A2′ or the second-type vertical Hall assemblies A3 ‘, A4’ to form a single sensing assembly. That is to say, a single sensing assembly may be composed of an even number of first-type vertical Hall assemblies A1′, A2′ or an even number of second-type vertical Hall assemblies A3′, A4′ coupled and connected. In addition, at least one of the first-type vertical Hall assemblies A1′, A2′ may be coupled and connected with at least one of the second-type vertical Hall assemblies A3′, A4′ (such as, A1′ and A3′, or A1′ and A4′) to form a single sensing assembly. In the embodiment shown in FIG. 14, at least one of the first-type vertical Hall assemblies A1′ and A2′ and at least one of the second-type vertical Hall assemblies A3′ and A4′ are coupled and connected as a group (such as, A1′ and A3′, or A1′ and A4′) to generate an output of the magnetic field in a single direction. Therefore, another at least one of the first-type vertical Hall assemblies A1′, A2′ and another at least one of the second-type vertical Hall assemblies A3′, A4′ are also coupled and connected as a group to produce an output to the magnetic field in another direction, wherein the numbers of the first-type vertical Hall assemblies and second-type vertical Hall assemblies coupled and connected in each group are equal.

In other embodiments, there is no coupling relationship between any two vertical Hall assemblies among the first-type vertical Hall assemblies A1′, A2′ and the second-type vertical Hall assemblies A3′, A4′, so that the vertical Hall assemblies work as independent devices. It should be noted that if there is no coupling relationship between any two vertical Hall assemblies among the first-type vertical Hall assemblies A1′, A2′ and the second-type vertical Hall assemblies A3′, A4′, only one first-type of vertical Hall assembly and only one second-type vertical Hall assembly can be used to obtain the outputs of the parallel magnetic field and antiparallel magnetic field of the first-type vertical Hall assembly and the second-type vertical Hall assembly by the measurement method above shown in FIG. 12A-FIG. 12B, and further the external magnetic field components parallel to the second direction D2 and the third direction D3 are obtained. Otherwise, at least two first-type vertical Hall assemblies A1′, A2′ and at least two second-type vertical Hall assemblies A3′, A4′ are required to couple and connect to obtain the outputs of parallel magnetic field and antiparallel magnetic field of first-type vertical Hall assembly and second-type vertical Hall assembly respectively.

Therefore, the external magnetic field components parallel to the second direction D2 and the third direction D3 are sensed and output by the first-type vertical Hall assemblies A1′, A2′ and the second-type vertical Hall assemblies A3′, A4′.

In addition, the vertical Hall assembly also comprises at least one third-type vertical Hall assembly B1′, B2′, and the sensing direction of each of the third-type vertical Hall assemblies B1′, B2′ is the first direction D1 on the first plane. In the present embodiment, the number of the third-type vertical Hall assemblies B1′, B2′ is 2, and they are arranged along the second direction D2.

There may be an even number of vertical Hall assemblies (such as, B1′, B2′) coupled and connected among the third-type vertical Hall assemblies B1′, B2′ to form a single sensing assembly. That is to say, a single sensing assembly may be composed of an even number of third-type vertical Hall assemblies B1′, B2′ coupled and connected. A main function of the coupling and connecting the vertical Hall assemblies is to reduce the output drift of the assemblies under zero magnetic field. In other embodiments, there is no coupling relationship between any two vertical Hall assemblies among the third-type vertical Hall assemblies B1′, B2′. Therefore, the external magnetic field component parallel to the second direction D2 is sensed and output by the third-type vertical Hall assemblies B1′, B2′.

### The Third Embodiment Three-Axis Hall Magnetometer

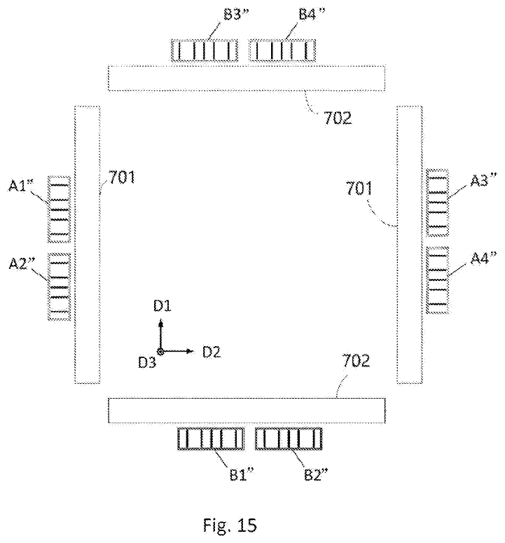

As shown in FIG. 15, a three-axis Hall magnetometer according to the third embodiment of the present application is composed of a substrate (not shown in the figure) located on the first plane, and two first-type magnetic beam deflection structures 701, two second-type magnetic beam deflection structures 702, at least one first-type vertical Hall assembly A1″, A2″, at least one second-type vertical Hall assembly A3″, A4″, at least one third-type vertical Hall assembly B1″, B2″ and at least one fourth-type vertical Hall assembly B3″, B4″ fixed on the substrate.

As shown in FIG. 15, each magnetic beam deflection structure 701, 702 is in an elongated shape and has a large length-width ratio which is greater than 2. In the present embodiment, the number of the first-type magnetic beam deflection structure 701 is 2 and both of them extend along the first direction D1 on the first plane, and the number of the second-type magnetic beam deflection structure 702 is 2 and both of them extend along the second direction D2 perpendicular to the first direction on the first plane. Among the relative relationships between the first-type magnetic beam deflection structure 701 and the second-type magnetic beam deflection structure 702, the angle between their long axes is important rather than the relative position between them, so there is a relatively large degree of freedom in the arrangement. The combination of them can be may be square-shaped, rectangular-shaped, “+”-shaped or in any other shape.

The vertical Hall assemblies comprise at least one first-type vertical Hall assembly A1″, A2″ and at least one second-type vertical Hall assembly A3″, A4″ disposed near the first-type magnetic beam deflection structures 701. Each of the first-type vertical Hall assemblies A1″, A2″ and the second-type vertical Hall assemblies A3″, A4″ has the same sensing direction which is perpendicular to the extension direction of the first-type magnetic beam deflection structures 701, namely, the second direction D2 perpendicular to the first direction D1 on the first plane. Each of the first-type vertical Hall assemblies A1″, A2″ and the second-type vertical Hall assemblies A3″, A4″ contains five electrodes. Each electrode of the first-type vertical Hall assembly A1″, A2″ and the second-type vertical Hall assembly A3″, A4″ extends along the second direction D2, so that it can be used to measure the magnetic field in the second direction D2. In addition, the first-type vertical Hall assemblies A1″, A2″ and the second-type vertical Hall assemblies A3″, A4″ are located on the first side and the second side of their nearby first-type magnetic beam deflection structures 701 respectively. The first side and the second side are the two opposite sides on which the long sides of the first-type magnetic beam deflection structure 701 are located. In the present embodiment, the number of first-type vertical Hall assemblies A1″, A2″ is 2, and the number of second-type vertical Hall assemblies A3″, A4″ is 2. The first-type vertical Hall assemblies A1″, A2″ are located on the first side of one of the first-type magnetic beam deflection structures 701, and the second-type vertical Hall assemblies A3″, A4″ are located on the second side of the other one of the magnetic beam deflection structures 701.

Similarly, the vertical Hall assemblies also comprises at least one third-type vertical Hall assembly B1″, B2″ and at least one fourth-type vertical Hall assembly B3″, B4″ disposed near the second-type magnetic beam deflection structures 702. Each of the third-type vertical Hall assemblies B1″, B2″ and fourth-type vertical Hall assemblies B3″, B4″ has the same sensing direction which is perpendicular to the extension direction of the second-type magnetic beam deflection structures 702, namely, the first direction D1 on the first plane. Each electrode of the third-type vertical Hall assemblies B1″, B2″ and the fourth-type vertical Hall assemblies B3″, B4″ is parallel to the first direction D1. The third-type vertical Hall assemblies B1″, B2″ and the fourth-type vertical Hall assemblies B3″, B4″ are located on the first side and the second side of their nearby second-type magnetic beam deflection structures 503 respectively. The first side and the second side of the second-type magnetic beam deflection structure 503 are the two opposite sides on which the long sides of the second-type magnetic beam deflection structure 503 are located. In the present embodiment, the number of third-type vertical Hall assemblies B1″, B2″ is 2, and the number of fourth-type vertical Hall assemblies B3″, B4″ is 2. The third-type vertical Hall assemblies B1″, B2″ are located on the first side of one of the second-type magnetic beam deflection structures 702, and the fourth-type vertical Hall assemblies B3″, B4″ are located on the second side of the other one of magnetic beam deflection structures 702.

Similar to other embodiments above, there may be an even number of vertical Hall assemblies (such as, A1″, A2″) among the first-type vertical Hall assemblies A1″, A2″ or the second-type vertical Hall assemblies A3″, A4″ to form a single sensing assembly. That is to say, a single sensing assembly can be composed of an even number of first-type vertical Hall assemblies A1″, A2″ or even number of second-type vertical Hall assemblies A3″, A4″ coupled and connected. In addition, at least one of the first-type vertical Hall assemblies A1″, A2″ may be coupled with at least one of the second-type vertical Hall assemblies A3″, A4″ (such as, A1″ and A3″, or A1″ and A4″) to form a single sensing assembly. In the embodiment shown in FIG. 14, at least one of the first-type vertical Hall assemblies A1″, A2″ and at least one of the second-type vertical Hall assemblies A3″, A4″ are coupled and connected as a group (such as, A1″ and A3″, or A1″ and A4″) to generate an output of the magnetic field in a single direction, and another at least one of the first-type vertical Hall assemblies A1″, A2″ and another at least one of the second-type vertical Hall assemblies A3″, A4″ are also coupled and connected as a group to generate an output of the magnetic field in another direction, wherein the numbers of the first-type vertical Hall assemblies and the second-type vertical Hall assemblies coupled and connected in each group are equal.

In other embodiments, there is no coupling relationship between any two vertical Hall assemblies among the first-type vertical Hall assemblies A1″, A2″ and the second-type vertical Hall assemblies A3″, A4″, so that the vertical Hall assemblies work as independent devices. It should be noted that, if there is no coupling relationship between any two vertical Hall assemblies among the first-type vertical Hall assemblies A1″, A2″ and second-type vertical Hall assemblies A3″, A4″, only one first-type vertical Hall assembly and only one second-type vertical Hall assembly can be used to obtain the outputs of parallel magnetic field and antiparallel magnetic field of the first-type vertical Hall assembly and the second-type vertical Hall assembly by the measurement method above shown in FIG. 12A-FIG. 12B, and further the external magnetic field components parallel to the second direction D2 and the third direction D3 are obtained. Otherwise, at least two first-type vertical Hall assemblies A1″, A2″ and at least two second-type vertical Hall assemblies A3″, A4″ are required to couple and connect to obtain the outputs of parallel magnetic field and antiparallel magnetic field of first-type vertical Hall assembly and second-type vertical Hall assembly respectively.

Therefore, the external magnetic field components parallel to the second direction D2 and the third direction D3 are sensed and output by the first-type vertical Hall assemblies A1″, A2″ and the second-type vertical Hall assemblies A3″, A4″.

There is no coupling relationship between any two vertical Hall assemblies among the third-type vertical Hall assemblies B1″, B2″ and the fourth-type vertical Hall assemblies B3″, B4″, so that the vertical Hall assemblies work as independent devices. Alternatively, there may be a plurality of vertical Hall assemblies (such as B1″, B2″) coupled and connected among the third-type vertical Hall assemblies B1″, B2″ or the fourth-type vertical Hall assemblies B3″, B4″ to form a single sensing assembly. In addition, at least one of the third-type vertical Hall assemblies B1″, B2″ and at least one of the fourth-type vertical Hall assemblies B3″, B4″ (for example, B1″ and B3″, or B1″ and B4″) may be coupled and connected to form a single sensing assembly.

Therefore, the external magnetic field components parallel to the first direction D1 and the third direction D3 are sensed and output by the third-type vertical Hall assemblies B1″, B2″ and the fourth-type vertical Hall assemblies B3″, B4″.

### The Fourth Embodiment Three-Axis Hall Magnetometer Combined with Coil

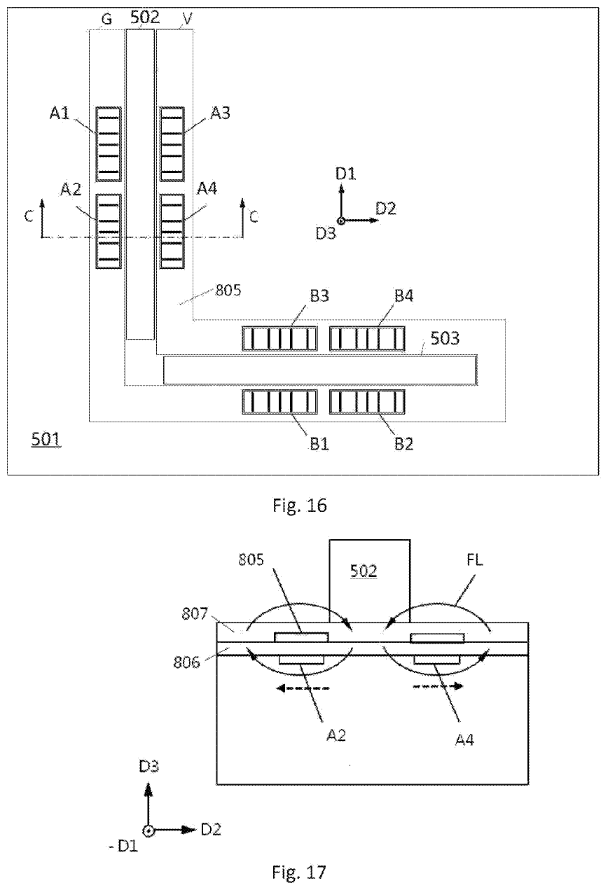

As shown in FIG. 16, the structure of the three-axis Hall magnetometer combined with the coil according to the fourth embodiment of the present application is generally the same as that of the three-axis Hall magnetometer in the first embodiment of the present application. The only difference is that the three-axis Hall magnetometer also comprises at least one coil 805, which is located in the area adjacent to all vertical Hall assemblies to generate a reference magnetic field around the vertical Hall assemblies by using the coil 805, and the reference magnetic field is used for the calibration or function test of the three-axis Hall magnetometer of the present application. In addition, since the first-type vertical Hall assemblies A1, A2 and the second-type vertical Hall assemblies A3, A4 are symmetrically set relative to the first-type magnetic beam deflection structure 502, and the third-type vertical Hall assemblies B1, B2 and the fourth-type vertical Hall assemblies B3, B4 are symmetrically set relative to the second-type magnetic beam deflection structure 503, the coil 805 is symmetrically set relative to the first-type magnetic beam deflection structure 502 and the second-type magnetic beam deflection structure 503 to ensure the symmetry of the generated magnetic field. The number of coils 805 can be set as required. In the present embodiment, the number of the coils 805 is 1, and two ends of the coil 805 are connected with power terminal V and ground terminal G respectively.

As shown in FIG. 17, the coil 805 can be located above all vertical Hall assemblies (such as the first-type vertical Hall assembly A2 and the second-type vertical Hall assembly A4 in FIG. 17). A first electrical insulating layer 806 is arranged between the vertical Hall assemblies and the coil 805, and a second electrical insulating layer 807 is arranged between the coil 805 and the magnetic beam deflection structure (as shown in the first-type magnetic beam deflection structure 502 in FIG. 17). When a current flows from the power terminal V in FIG. 16 to the ground terminal G via the coil 805, a magnetic field is generated around the coil 805, and its magnetic lines FL are shown in FIG. 17. The first-type vertical Hall assembly A2 and the second-type vertical Hall assembly A4 respectively sense a magnetic field component parallel to the second direction D2 and a magnetic field component antiparallel to the second direction D2, as shown by the dotted arrows in FIG. 17. Therefore, the outputs of the antiparallel magnetic fields of the first-type vertical Hall assembly and the second-type vertical Hall assembly can be corrected.

### The Fifth Embodiment Three-Axis Hall Magnetometer Combined with Coil

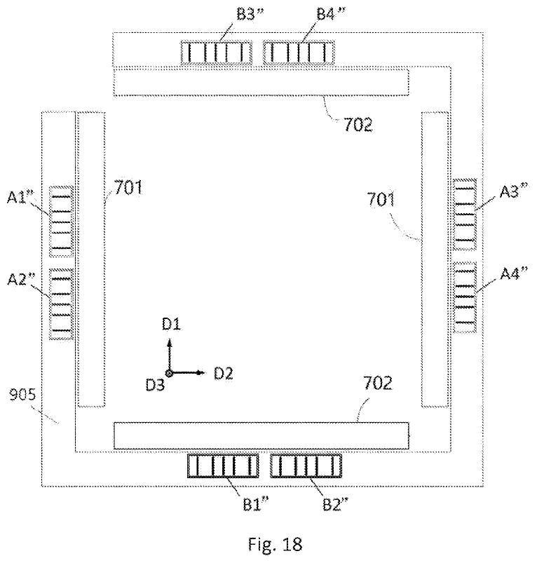

As shown in FIG. 18, the structure of the three-axis Hall magnetometer combined with a coil according to the fifth embodiment of the present application is generally the same as that of the three-axis Hall magnetometer in the third embodiment of the present application, except that the three-axis Hall magnetometer also comprises at least one coil 905, which is located in the area adjacent to all vertical Hall assemblies to generate a reference magnetic field around the vertical Hall assemblies by using the coil 905, and the reference magnetic field is used for the calibration or function test of the three-axis Hall magnetometer of the present application.

In other embodiments, the coil can also be combined with the three-axis Hall magnetometer in other embodiments of the present application, such as the three-axis Hall magnetometer with one magnetic beam deflection structure.

The above is only a preferred embodiment of the present application and is not intended to limit the scope of the present application. The above embodiments of the present application can also make various changes. For example, the angle between the extension directions of the first-type magnetic beam deflection structure and the second-type magnetic beam deflection structure can also be between 60 and 120 degrees, while the sensing directions of the first-type vertical Hall assemblies and the second-type vertical Hall assemblies are still perpendicular to the extension direction of the first-type magnetic beam deflection structure, and the sensing directions of the third-type vertical Hall assemblies and the fourth-type vertical Hall assemblies are still perpendicular to the extension direction of the second-type magnetic beam deflection structure. All simple and equivalent variations and modifications made according to the claims and specifications of the present application fall into the scope of protection of the claims of the present application. What is not described in detail in this application is all conventional technical contents.

1. A three-axis Hall magnetometer which is integrated on a single substrate, comprising at least one magnetic beam deflection structure located on a first plane and a plurality of vertical Hall assemblies located on a second plane parallel to the first plane, and not comprising any planar Hall assembly;
wherein, each magnetic beam deflection structure is in an elongated shape with two parallel long sides and a length-width ratio greater than 2, and the magnetic beam deflection structure comprises at least one first-type magnetic beam deflection structure which extends in a first direction on the first plane;
wherein, a sensing direction of each vertical Hall assembly is parallel to the first plane;
wherein, the plurality of vertical Hall assemblies comprise at least one first-type vertical Hall assembly and at least one second-type vertical Hall assembly, each of which is located near one long side of the first-type magnetic beam deflection structure and has a sensing direction perpendicular to the long side of the first-type magnetic beam deflection structure, and the first-type vertical Hall assembly is located on a first side of its nearby first-type magnetic beam deflection structure and the second-type vertical Hall assembly is located on a second side of its nearby first-type magnetic beam deflection structure, wherein the first side and the second side of the first-type magnetic beam deflection structure are two opposite sides on which long sides of the first-type magnetic beam deflection structure are located; and
wherein, the plurality of vertical Hall assemblies further comprise at least one third-type vertical Hall assembly which has a sensing direction different from those of the first-type vertical Hall assembly and the second-type vertical Hall assembly.

2. The three-axis Hall magnetometer according to claim 1, wherein the magnetic beam deflection structure also comprises at least one second-type magnetic beam deflection structure, a long axis of each of which extends along a second direction different from the first direction on the first plane; the plurality of vertical Hall assemblies also comprise at least one fourth-type vertical Hall assembly, wherein each of the third-type vertical Hall assembly and the fourth-type vertical Hall assembly is located near one long side of the second-type magnetic beam deflection structure and has a sensing direction perpendicular to a long side of the second-type magnetic beam deflection structure; and the third-type vertical Hall assembly is located on a first side of its nearby second-type magnetic beam deflection structure and the fourth-type vertical Hall assembly is located on a second side of its nearby second-type magnetic beam deflection structure, wherein the first side and the second side of the second-type magnetic beam deflection structure are two opposite sides on which long sides of the second-type magnetic beam deflection structure are located.

3. The three-axis Hall magnetometer according to claim 1, wherein the magnetic beam deflection structure is composed of a magnetic material with high permeability, and relative permeability of the magnetic material is higher than 100.

4. The three-axis Hall magnetometer according to claim 1, wherein each vertical Hall assembly is separated from its nearby magnetic beam deflection structure in vertical direction by an electrical insulating layer, and every two vertical Hall assemblies are separated from each other in a direction on the second plane.

5. The three-axis Hall magnetometer according to claim 2, wherein the first direction and the second direction are perpendicular to each other.

6. The three-axis Hall magnetometer according to claim 2, wherein a number of first-type magnetic beam deflection structures and a number of second-type magnetic beam deflection structures are both two, wherein the first-type vertical Hall assembly is located on the first side of one of two first-type magnetic beam deflection structures, the second-type vertical Hall assembly is located on the second side of other one of two first-type magnetic beam deflection structures, the third-type vertical Hall assembly is located on the first side of one of two second-type magnetic beam deflection structures, and the fourth-type vertical Hall assembly is located on the second side of other one of two second-type magnetic beam deflection structures.

7. The three-axis Hall magnetometer according to claim 2, wherein a number of third-type vertical Hall assemblies and a number of fourth-type vertical Hall assemblies are both multiple, wherein the third-type vertical Hall assemblies are arranged along the long side on the first side of the second-type magnetic beam deflection structure, and the fourth-type vertical Hall assemblies are arranged along the long side on the second side of the second-type magnetic beam deflection structure.

8. The three-axis Hall magnetometer according to claim 2, wherein there are an even number of vertical Hall assemblies coupled and connected among third-type vertical Hall assemblies or fourth-type vertical Hall assemblies;
or, at least one of the third-type vertical Hall assemblies and at least one of the fourth-type vertical Hall assemblies are coupled and connected as a group, and another at least one of the third-type vertical Hall assemblies and another at least one of the fourth-type vertical Hall assemblies are also coupled and connected as a group, wherein the numbers of the third-type vertical Hall assemblies and the fourth-type vertical Hall assemblies coupled and connected in each group are equal.

9. The three-axis Hall magnetometer according to claim 1, wherein a number of first-type vertical Hall assemblies and a number of second-type vertical Hall assemblies are both multiple, wherein the first-type vertical Hall assemblies are arranged along the long side on the first side of the first-type magnetic beam deflection structure, and the second-type vertical Hall assemblies are arranged along the long side on the second side of the first-type magnetic beam deflection structure.

10. The three-axis Hall magnetometer according to claim 1, wherein there are an even number of vertical Hall assemblies coupled and connected among first-type vertical Hall assemblies or second-type vertical Hall assemblies;
or, at least one of the first-type vertical Hall assemblies and at least one of the second-type vertical Hall assemblies are coupled and connected as a group, and another at least one of the first-type vertical Hall assemblies and another at least one of the second-type vertical Hall assemblies are also coupled and connected as a group, wherein the numbers of the first-type vertical Hall assemblies and the second-type vertical Hall assemblies coupled and connected in each group are equal.
